(19) United States
(12) Patent Application Publication
(10) Pub. No.: US 2026/0287640 A1
(43) Pub. Date: Sep. 24, 2026

(54) CURRENT SENSING CIRCUIT AND METHOD FOR SENSING A SOURCE DRAIN CURRENT OF A SWITCH TRANSISTOR

(71) Applicant: Infineon Technologies Austria AG, Villach (AT)

(72) Inventors: Abhishek JAIN, Delhi (IN); Suraj Somashekara KUMAR, Bantwal (IN); Ramesh KARPUR GOPINATHAN, Bengaluru (IN)

(21) Appl. No.: 19/570,492

(22) Filed: Mar. 18, 2026

(30) Foreign Application Priority Data
Mar. 21, 2025 (DE) 102025111091.3

(51) Int. Cl. G01R 31/26

(52) U.S. Cl. CPC G01R 31/2621

(57) ABSTRACT

A sensing circuit for sensing a source drain current through a switch transistor, comprising an output branch for superposing output currents of a first amplifier and a second amplifier and measuring the superposed output current.

### RELATED APPLICATIONS

This application claims priority to earlier filed German Patent Application Serial Number 10 2025 111091.3, filed on Mar. 21, 2025, the entire teachings of which are incorporated herein by this reference.

### BACKGROUND

Current sensing for sensing a source drain current of a power device is generally known in the field of electronic motor design. Thereby, a current flowing through a switch transistor of a power device has to be sensed. In principle, the current can flow form a drain of the switch transistor to a source or the other way around. Accordingly, a source drain current can switch signs and a circuit and/or method for sensing a source drain current should be configured for bi-directional current sensing.

When the current flows from source to drain then a negative charge pump can become necessary. Negative charge pumps are costly and in many cases not feasible.

### BRIEF DESCRIPTION

Therefore, there is a need for improvement of bi-directional current sensing.

This objective is solved by a sensing circuit for sensing a source drain current according to embodiment 1 and method for sensing a source drain current according to embodiment 15. Thus, a sensing circuit according to the proposed solution comprises at least:
a first supply connected to a first input terminal of a first operational amplifier, said first supply is configured to be connected to a source terminal of the switch transistor via a first transistor arrangement;
a second supply connected to a first input terminal of a second operational amplifier, said second supply is configured to be connected to the source terminal of the switch transistor via a second transistor arrangement;
a third supply configured to be connected to a drain terminal of the switch transistor via a sense transistor, whereby a gate terminal of the sense transistor is configured to be connected to a gate terminal of the switch transistor;
a first voltage adjustment branch setting a second terminal of the first amplifier to a first input voltage based on a voltage of the third supply and shifted by an offset;
a second voltage adjustment branch setting a second terminal of the second amplifier to the offset; and
an output branch for superposing output currents of the first amplifier and the second amplifier and measuring the superposed output current.

The proposed sensing circuit is configured to be connected in a properly mounted state to a switch transistor of a power device by i) connecting the first supply to a source terminal of the switch transistor via the first transistor arrangement and ii) connecting the second supply to the source terminal of the switch transistor via the second transistor arrangement and iii) connecting the third supply to a drain terminal of the switch transistor via the sense transistor and iv) connection a gate terminal of the switch transistor to the gate terminal of the sense transistor with a predetermined gate potential. Thereby, the first and second transistor arrangements can be configured to stabilize currents provided via the first and second supply and reduce a voltage dependency of the provided currents. Additionally, the proposed sensing circuit works without a negative supply. This can reduce the costs. The proposed sensing circuit can be used to sense a source drain current as follows.

The output voltage of the first amplifier V_{out,1} defines the current I_{out,1} provided by the first supply via the resistance R₁ of the first transistor arrangement:

$${I}_{out , 1} = \frac{{V}_{out , 1}}{{R}_{1}} .$$

As will be apparent to a person skilled in the art of electrical engineering, the first and second operational amplifiers can be voltage amplifiers with a differential input. The input terminal can comprise a non-inverting input terminal and an inverting input terminal. The operational amplifiers can be configured to amplify the difference in voltage between both input terminals. In particular, the operational amplifiers can be configured as closed-loop amplifier with feedback of an output voltage to one of the input terminals, in particular with feedback to the inverting input terminal. Thus, the voltage at both input terminals of one of the operational amplifiers can be considered equal. The voltage at both input terminals of the first amplifier can be V_{out,1}.

Additionally, the voltage at the input terminals of the first amplifier is set via the first voltage adjustment branch a first input voltage. The first input voltage can be based on a voltage of the third supply V_{S}, i.e. a function ƒ( ) of V_{S}, which is shifted by an offset V_{off}.

$${V}_{out , 1} = f ( {V}_{S} ) + {V}_{off} .$$

The function ƒ( ) of V_{S} can be any differentiable real function mapping an input voltage value to an output voltage value. In particular, ƒ( ) can be an algebraic function. This can simplify the calculation of the drain source current.

The voltage at both input terminals of the first amplifier can be defined by the voltage of the third supply V_{S}, the relation to the voltage of the third supply ƒ(V_{S}) and the offset V_{off}.

In the properly mounted state, a drain voltage V_{DS} of the switch transistor is passed through the sense transistor and thus determined by the third supply:

$${V}_{S} = {V}_{DS} .$$

Considering a general voltage current relation V_{DS}=I_{DS}·R_{DS} the voltage at the input terminals of the first amplifier can be rewritten as:

$${V}_{out , 1} = f ( {I}_{DS} {R}_{DS} ) + {V}_{off} .$$

With that in mind, the current I_{out,1} provided by the first supply via the first transistor arrangement is:

$${I}_{out , 1} = \frac{f ( {I}_{DS} {R}_{DS} ) + {V}_{off}}{{R}_{1}} .$$

Considering the second amplifier, the voltage of both input terminals are also the same and set by the second voltage adjustment branch to V_{off}. Thus, the output current I_{out,2} provided by the second supply via the second transistor arrangement with a resistance R₂ is:

$${I}_{out , 2} = \frac{{V}_{off}}{{R}_{2}} .$$

Since, in the properly mounted state the first supply as well as the second supply are connected to the source terminal of the switch transistor, they define a common source current I_{CS}:

$${I}_{CS} = {I}_{out , 1} - {I}_{out , 2} = \frac{f ( {I}_{DS} {R}_{DS} ) + {V}_{off}}{{R}_{1}} - \frac{{V}_{off}}{{R}_{2}} .$$

Thus, if the function ƒ( ) the offset V_{off} and the resistance of the transistor arrangements R₁, R₂ are known, the drain source current I_{DS} can be calculated by measuring the common source current I_{CS}. Here, due to the proposed voltage adjustment branches in combination with the proposed connection of the operational amplifiers to a switch transistor, no negative supplies become necessary which reduces the costs.

According to an embodiment of the proposed sensing circuit, the first voltage adjustment branch can be configured to provide a first input voltage which is a voltage of the third supply scaled by a factor a and shifted by the offset V_{off}. This means, that the above-mentioned function ƒ( ) defining a relationship between the voltage at both input terminals of the first operation amplifier and the voltage of the third supply V_{S} is 1/a:

$${V}_{out , 1} = f ( {V}_{S} ) + {V}_{off} = \frac{{V}_{S}}{a} + {V}_{off} .$$

Hereby, the factor a can be any real number greater zero. Such a functional relationship can be easy to implement and improve calculation of the drain source current based on the common source current.

According to an embodiment of the proposed sensing circuit, the first voltage adjustment branch can comprise a voltage divider for scaling the voltage of the third supply. Thus, the above-mentioned relationship between the voltage at both input terminals of the first operation amplifier and the voltage of the third supply V_{S} can be implemented using the voltage divider. Therefore, the voltage divider can be configured to have an input connected to the third supply and to have an output connected to the second terminal of the first amplifier. The voltage divider might be realized by two resistances connected in series. This can reduce costs of the proposed sensing circuit.

According to an embodiment of the proposed sensing circuit, the first voltage adjustment branch and the second voltage adjustment branch can be configured to reduce voltages on each terminal of both amplifiers to a maximum of 3.3 V. This can reduce costs for components and can improve compatibility with established manufacturing processes.

According to an embodiment of the proposed sensing circuit, the second terminals of both amplifiers are connected to a circuit node with a common reference potential. Hereby, one or both of the second terminals can be connected to the common reference potential via one or more resistors. Thus, as throughout the whole document the term connection includes a direct connection as well as indirect connection. Via the common reference potential, a floating voltage source can be dispensable.

Additionally, according to another embodiment of the proposed sensing circuit, the circuit node can be connected to an output of a third operational amplifier providing the reference potential. The third operational amplifier can be a closed-loop amplifier with negative feedback. Hence, the reference potential can be provided to a non-inverting input terminal of the third amplifier and the output can be fed back to the inverting input terminal of the third amplifier. Hereby, the output can be a stabilized value of the reference potential. The output of the third amplifier can be connected to the second terminals of the first amplifier and the second amplifier.

According to an embodiment of the proposed sensing circuit, gate terminals of the first transistor arrangement and the second transistor arrangement can be connected to a further circuit node to be set to a common potential. In one exemplary embodiment, the common potential can be grounded.

According to an embodiment of the proposed sensing circuit, the gate terminals of the switch transistor, the first transistor arrangement, the second transistor arrangement and the sense transistor are connected to a further circuit node to be set to a common potential.

According to an embodiment of the proposed sensing circuit, the first transistor arrangement and the second transistor arrangement can each comprise two transistors. Thus, both transistor arrangements can share a principial structure. This can reduce production costs and improve the calculation of the drain source current.

Additionally, according to another embodiment of the proposed sensing circuit, the transistors of the first transistor arrangement and the second transistor arrangement can be connected in series. For example, each of the first supply together with the first transistor arrangement and the second supply together with the second transistor arrangement can be a cascode power source.

According to an embodiment of the proposed sensing circuit, the first transistor arrangement and the second transistor arrangement can be identical in construction. This means that both transistor arrangements can comprise the same components which are arranged and connected in the same way. This can further reduce the production costs and improve the calculation of the drain source current. For example, the resistance of both transistor arrangements can be the same which means R₁=R₂. Thus, the equation for the common source current I_{CS} can be simplified:

$${I}_{CS} = {I}_{out , 1} - {I}_{out , 2} = \frac{f ( {I}_{DS} {R}_{DS} ) + {V}_{off}}{{R}_{1}} - \frac{{V}_{off}}{{R}_{1}} = \frac{f ( {I}_{DS} {R}_{DS} )}{{R}_{1}} .$$

Considering the embodiment in which the function ƒ( ) is given via the scaling factor a the common source current I_{CS} is:

$${I}_{CS} = {I}_{out , 1} - {I}_{out , 2} = \frac{{I}_{DS} {R}_{DS}}{{aR}_{1}} .$$

In yet a further embodiment, the resistance of both transistor arrangements can be set to a multiple N of the resistance of the switch transistor R_{DS}:

$${R}_{1} = {R}_{2} = N {R}_{DS} , with N ∈ ℝ > 0 .$$

Thus, the common source current I_{CS} is:

$${I}_{CS} = {I}_{out , 1} - {I}_{out , 2} = \frac{{I}_{DS}}{a N} .$$

Considering the embodiment of the proposed sensing circuit where the second terminals of both amplifiers are connected to the common reference potential V_{ref}, the offset V_{off} can be defined by the reference potential V_{ref}:

$${V}_{off} = b {V}_{ref} , with b ∈ ℝ > 0 ,$$

The factor b can be defined by the way the reference potential V_{ref} is connected to the second terminals of the first and the second amplifier. For example, the reference potential V_{ref} can be connected to the second terminal of the first amplifier via a resistance R₃ while the second terminal of the first amplifier is also connected to the third supply via resistance R₄. Thereby, the offset V_{off} provided to the second terminal of the first amplifier can be

$${V}_{ref} \frac{{R}_{4}}{{R}_{3} + {R}_{4}} .$$

The overall voltage provided to the second terminal of the first amplifier can be

$${I}_{DS} {R}_{DS} \frac{{R}_{3}}{{R}_{3} + {R}_{4}} + {V}_{off .}$$

Hence, the factors a, b can be:

$$b = \frac{{R}_{4}}{{R}_{3} + {R}_{4}} , \\ \frac{1}{a} = \frac{{R}_{3}}{{R}_{3} + {R}_{4}} .$$

Thus, the common source current I_{CS} is:

$${I}_{CS} = {I}_{out , 1} - {I}_{out , 2} = \frac{{I}_{DS}}{N} \frac{{R}_{3}}{{R}_{3} + {R}_{4}} .$$

According to the proposed sensing circuit the same offset V_{off} has to be provided as voltage to the second terminal of the second amplifier. Thus, the reference potential V_{ref} can be connected to the second terminal of the second amplifier via a resistance R₃ while the second terminal of the second amplifier is also connected to a ground potential via resistance R₄.

According to an embodiment of the proposed sensing circuit the output branch can comprise at least two current mirrors for superposing the output of the two operational amplifiers. Hereby, superposing the output means providing I_{CS} at one node. Thus, the common source current I_{CS} can be measured more easily.

According to an embodiment of the proposed sensing circuit, each current mirror can comprise an input transistor and an output transistor. A drain terminal of each of the input transistors and each of the output transistors can be set to a common potential. A source terminal of one of the input transistors can be connected to the first input terminal of the first amplifier and a source terminal of the other of the input transistors can be connected to the first input terminal of the second amplifier. Additionally, the output of each of the amplifiers can be connected to the gate terminal of one of the current mirrors. Thus, the output branch can be configured to effectively provide I_{CS}.

According to another aspect, the proposed solution also relates to a sensing device for sensing a current trough a power device with the proposed sensing circuit and a switch transistor. Thereby, the switch transistor comprises a source terminal connected to the drain terminals of the transistor arrangements and comprises a gate terminal connected to the gate terminal of the sense transistor and comprises a drain terminal connected to the drain terminal of the sense transistor. Additionally, the switch transistor is configured to be connected to the power device.

Explanations of particular embodiments and advantages of the sensing circuit apply analogously to the claimed sensing device.

Throughout the whole document all supplies can be DC supplies.

Furthermore, the above-mentioned objective is also solved by the proposed method for sensing a source drain current through a switch transistor. The proposed method comprises at least the steps:

providing a first supply connected to a first input terminal of a first operational amplifier and connecting the first supply to a source terminal of the switch transistor via a first transistor arrangement;
providing a second supply connected to a first input terminal of a second operational amplifier and connecting the second supply to the source terminal of the switch transistor via a second transistor arrangement;
providing a third supply and connecting the third supply to a drain terminal of the switch transistor via a sense transistor;
providing a connection of a gate terminal of the sense transistor with a gate terminal of switch transistor;
setting a second terminal of the first amplifier to a first Input voltage based on a voltage of the third supply and shifted by an offset;
setting a second terminal of the second amplifier to the offset;
superposing the output current of the first amplifier and the second amplifier; and
calculating the source drain current through the switch based on the superposed output current and a resistance multiplicity of the transistor arrangements with respect to a resistance of the switch transistor.

Here, the first and second transistor arrangements can stabilize currents provided via the first and second supply and reduce a voltage dependency of the provided currents. This can improve a result of the calculated source drain current. Additionally, the proposed method does not need a negative supply which can reduce the costs for a device configured to perform the proposed method.

Calculating the source drain current I_{DS} can be performed based on the following equation:

$${I}_{CS} = {I}_{out , 1} - {I}_{out , 2} = \frac{f ( {I}_{DS} {R}_{DS} ) + {V}_{off}}{{R}_{1}} - \frac{{V}_{off}}{{R}_{2}} .$$

Here, I_{CS} denotes the superposed output current of the first and second amplifier, ƒ( ) denotes a continuous differentiable real function, I_{DS} is the source drain current, R_{DS} is the resistance of the switch transistor, V_{off} is the voltage offset, R₁ is the resistance of the first transistor arrangement and R₂ is the resistance of the second transistor arrangement. Thus, by measuring the common source current I_{CS}, the source drain current I_{DS} can be calculated.

In an embodiment of the proposed method, the function ƒ( ) can be an algebraic function. Thus, the above-mentioned equation for calculating the source drain current can be solved for I_{DS}. This can simplify the calculation since no numeric approach is necessary. In particular, the function ƒ( ) can be

$$\frac{1}{a}$$

whereby a is a real number greater zero.

According to an embodiment in which two identical transistor arrangements are provided as the first transistor arrangement and the second transistor arrangement, the resistance of both transistor arrangements can be the same which means R₁=R₂. Thus, the source drain current can be calculated with:

$${I}_{CS} = {I}_{out , 1} - {I}_{out , 2} = \frac{f ( {I}_{DS} {R}_{DS} )}{{R}_{1}} .$$

Considering the embodiment in which the function ƒ( ) is given via the scaling factor a the common source current I_{CS} is:

$${I}_{CS} = {I}_{out , 1} - {I}_{out , 2} = \frac{{I}_{DS} {R}_{DS}}{{aR}_{1}} .$$

In yet a further embodiment the resistance of both transistor arrangements can be set to a multiple N of the resistance of the switch transistor R_{DS}:

$${R}_{1} = {R}_{2} = N {R}_{DS} , with N ∈ ℝ > 0 .$$

Thus, the source drain current I_{DS} can be calculated with:

$${I}_{CS} = {I}_{out , 1} - {I}_{out , 2} = \frac{{I}_{DS}}{a N} .$$

In an embodiment of the proposed method setting the second terminals of the first and second amplifier can comprise setting the second terminal of the first amplifier to

$${I}_{DS} {R}_{DS} \frac{{R}_{3}}{{R}_{3} + {R}_{4}} + {V}_{off}$$

and setting the second terminal of the second amplifier to

$${V}_{ref} \frac{{R}_{4}}{{R}_{3} + {R}_{4}} .$$

Thus, the drain source current I_{DS} can be calculated with:

$${I}_{CS} = {I}_{out . 1} - {I}_{out . 2} = \frac{{I}_{DS}}{N} \frac{{R}_{3}}{{R}_{3} + {R}_{4}} .$$

In particular, the proposed method comprises:
providing a sensing circuit according to the proposed solution;
connecting the drain terminals of the first and second transistor arrangements to a source terminal of a switch transistor;
connecting the gate terminal of the sense transistor to the gate terminal of the switch transistor;
connecting the drain terminal of the sense transistor to the drain terminal of the switch transistor;
measuring the common source current of the first and second amplifier and;
calculating the drain source current of the switch transistor.

Explanations of particular embodiments and advantages of the sensing circuit and sensing device apply analogously to the claimed method.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIG. 1 shows a circuit diagram of a first embodiment of the proposed sensing circuit;

FIG. 2 shows a circuit diagram of an embodiment of the proposed sensing device connected to a power device;

FIG. 3 shows another embodiment of the proposed sensing device;

FIG. 4 shows yet another embodiment of the proposed sensing device; and

FIG. 5 shows a sequence of steps according to an embodiment of the proposed method.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled. To give an example, two electrodes of a capacitor may be electrically insulated from each other and, at the same time, mechanically and capacitively coupled to each other, e.g., by means of an insulation, e.g., a dielectric.

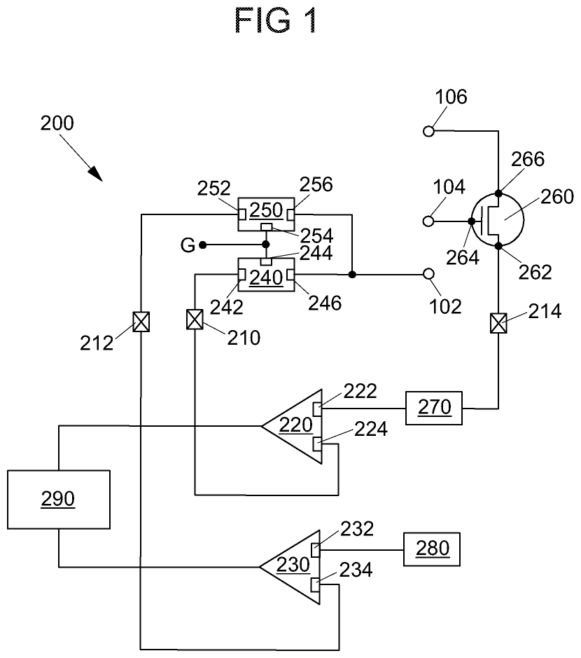

FIG. 1 shows a circuit diagram of a first embodiment of the proposed sensing circuit 200 for sensing a source drain current I_{DS} of a switch transistor 100.

The proposed sensing circuit 200 comprises at least a first supply 210 connected to a first input terminal 224 of a first operational amplifier 220, whereby the first supply 210 is configured to be connected to a source terminal 102 of the switch transistor 100 via a first transistor arrangement 240. The sensing circuit 200 also comprises a second supply 212 connected to a first input terminal 234 of a second operational amplifier 230, whereby the second supply 212 is configured to be connected to the source terminal 102 of the switch transistor 100 via a second transistor arrangement 250. Additionally, a third supply 214 of the sensing circuit 200 is configured to be connected to a drain terminal 106 of the switch transistor 100 via a sense transistor 260, whereby a gate terminal 264 of the sense transistor 260 is configured to be connected to a gate terminal 104 of the switch transistor 100. A first voltage adjustment branch 270 of the sensing circuit 200 is configured to set a second input terminal 222 of the first amplifier 220 to a first input voltage based on a voltage of the third supply 214 shifted by an offset. The sensing circuit 200 also comprises a second voltage adjustment branch 280, setting a second input terminal 232 of the second amplifier 230 to the offset, and an output branch 290 for superposing output currents I_{out,1}, I_{out,2} of the first amplifier 220 and the second amplifier 230 and measuring the superposed output current I_{CS}.

Thereby, in the embodiment shown in FIG. 1 the first transistor arrangement 240 comprises a source terminal 242 the first supply 210 is connected to. The first transistor arrangement 240 also comprises a drain terminal 246 which is configured to be connected to a source terminal 102 of a switch transistor 100 to be sensed. Also the second arrangement 250 comprises a source terminal 252 which is connected to the second supply 212. The second transistor arrangement 250 also comprises a drain terminal 256 configured to be connected to a source terminal 102 of the switch transistor 100. Furthermore, the first and the second transistor arrangements 240, 250 both comprise a gate terminal 245, 254 which are both connected and set to a potential G.

The third supply 214 is connected to the second input terminal 222 of the first amplifier 220 via a first voltage adjustment branch 270. Additionally, the third supply 214 is also connected to a source terminal 262 of the sense transistor 260. The sense transistor 260 comprises a gate terminal 264 which is configured to be connected to a gate terminal 104 of a switch transistor 100 to be sensed. The sense transistor 260 also comprises a drain terminal 266 which is configured to be connected to the drain terminal 106 of the switch transistor 100 to be sensed.

If a switch transistor 100, in particular a switch transistor 100 of a power device 400, is connected to the sensing circuit 200 shown in FIG. 1 via the connections mentioned above, a source drain current I_{DS} of the switch transistor 100 can be sensed. As set forth in the specification the superposed current I_{CS}, i.e. the common source current of the first amplifier 220 and the second amplifier 230, is connected to the drain source current I_{DS} via the following equation:

$${I}_{CS} = {I}_{out , 1} - {I}_{out , 2} = \frac{f ( {I}_{DS} {R}_{DS} ) + {V}_{off}}{{R}_{1}} - \frac{{V}_{off}}{{R}_{2}} .$$

Here, I_{CS} denotes the superposed output current of the first and second amplifiers 220, 230, ƒ( ) denotes a continuous differentiable real function which is defined by the first voltage adjustment branch 270, I_{DS} is the source drain current, R_{DS} is the resistance of the switch transistor 100, V_{off} is the voltage offset, R₁ is the resistance of the first transistor arrangement 240 and R₂ is the resistance of the second transistor arrangement 250.

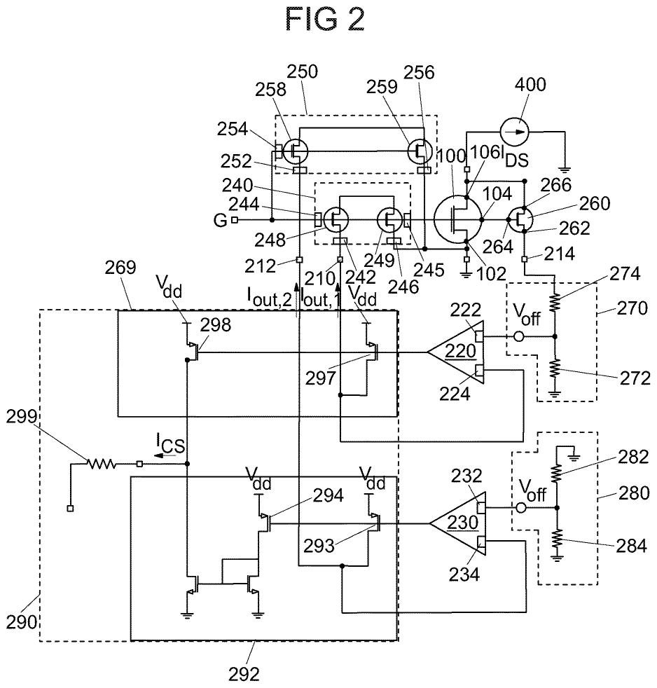

FIG. 2 shows an embodiment of a sensing device according to the proposed solution comprising a switch transistor 100 of a power device 400, whereby the switch transistor 100 is connected to an embodiment of the proposed sensing circuit 200.

The first transistor arrangement 240 together with the first supply 210 and the second transistor arrangement 250 together with the second supply 212 are configured as cascode power sources. Accordingly, each of the transistor arrangements 240, 250 comprise two transistors 248, 249, 258, 259 connected in series. A source terminal of the first of the transistors 248, 249 represents the source terminal 242 of the first transistor arrangements 240 and a drain terminal of the second of the transistors 248, 249 represents the drain terminal 246 of the first transistor arrangement 240. Analogously, a source terminal of the first of the transistors 258, 259 represents the source terminal 252 of the second transistor arrangement 250 and a drain terminal of the second of the transistors 258, 259 represents the drain terminal 256 of the second transistor arrangement 250. The gate terminals of the first and second transistors 248, 249, 258, 259 of both transistor arrangements 240, 250 are connected to the potential G.

As set out in the specification some of the transistors 248, 249, 258, 259 of the first and second transistor arrangement 240, 250 can be identical. In some embodiments, all of the transistors 248, 249, 258, 259 are identical. In particular, the resistance of the transistors 248, 249, 258, 259 can be identical and can be given as a multiple N of a resistance R_{DS} of the switch transistor 100.

In the embodiment shown in FIG. 2 the first and the second voltage adjustment branch 270, 280 are both configured with voltage dividers. Each voltage divider comprises two different resistors 272, 274, 282, 284. Each of the resistors 274, 282 shown the upper part of the voltage adjustment branches 270, 280 have the resistance (a−1) R₃, where a is a real number greater zero. Each of the resistors 272, 284 shown in the lower part of the voltage adjustment branches 270, 280 have the resistance R₃. Thus, the voltage divider of the first voltage adjustment branch 270 divides the voltage of the third supply 214 by a. The voltage divider of the second voltage adjustment branch 280 is grounded on both sides and thus provides a voltage of 0 V. The first and the second voltage adjustment branch 270, 280 are also configured with a further voltage source connected in series with the voltage dividers adding an offset V_{off} to the respective voltage provided by the voltage dividers. Hence, the first voltage adjustment branch 270 provides the voltage V₃ of the third supply 214 times 1/a plus the offset V_{off} to the second input terminal 222 of the first amplifier 220. The second voltage adjustment branch 280 provides the offset V_{off} to the second input terminal 232 of the second amplifier 230.

Thus, considering an embodiment with R₁=R₂ the common source current I_{CS} is:

$${I}_{CS} = {I}_{out , 1} - {I}_{out , 2} = \frac{{I}_{DS} {R}_{DS}}{{aR}_{1}} .$$

In the embodiment where the resistance of both transistor arrangements 240, 250 is a multiple N of the resistance of the switch transistor 100 the source drain current I_{DS} can be calculated with:

$${I}_{CS} = {I}_{out , 1} - {I}_{out , 2} = \frac{{I}_{DS}}{a N} .$$

The embodiment shown in FIG. 2 comprises also two current mirrors 292, 296 for superposing the output of the two operational amplifiers 220, 230. In this regards, superposing means providing I_{CS}=I_{out,1}−I_{out,2} at one node of the circuit. Each current mirror 292, 296 comprises an input transistor 293,297 and an output transistor 294, 298. A drain terminal of each of the input transistors 293,0297 and each of the output transistors 294, 298 are set to a common potential V_{dd}. A source terminal of the input transistors 297 of the first current mirror 296 is connected to the first input terminal 224 of the first amplifier 220, and a source terminal of the input transistor 293 of the second current mirror 292 is connected to the first input terminal 234 of the second amplifier 230. Additionally, the output of each of the amplifiers 220, 230 is connected to the gate terminals of both transistors 293, 294, 297, 298 of the respective current mirrors 292, 296. Hereby, the output branch 290 is configured to effectively provide I_{CS}, which is measured via a sense resistor 299.

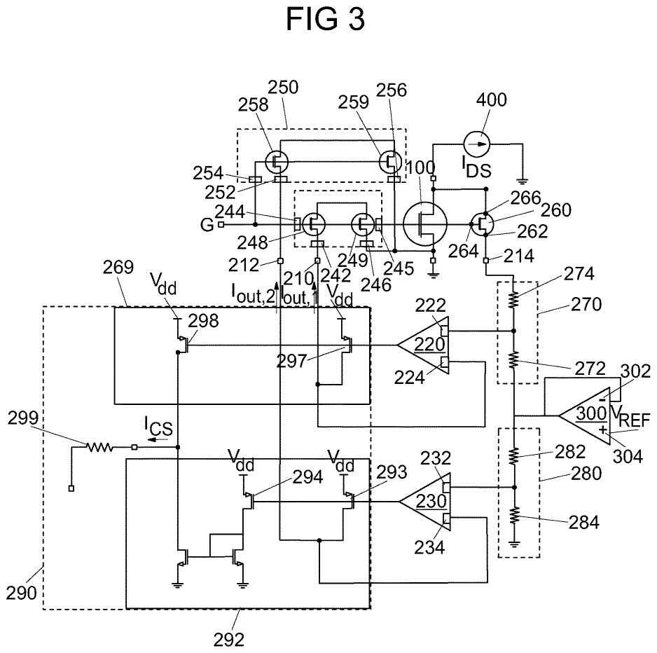

FIG. 3 shows another embodiment of the proposed sensing device. In contrast to the embodiment shown in FIG. 2 both voltage adjustment branches 270, 280 are connected to a circuit node with a common reference potential V_{ref}. Thereby, the offset V_{off} provided by both voltage adjustment branches 270, 280 to the second input terminals 222, 232, of the both amplifiers 220, 230 is defined via the reference potential V_{ref}. The reference potential V_{ref} itself is provided via an output of a third operational amplifier 300 with a negative feedback configuration. Accordingly, the feedback of the third amplifier's output is provided to the inverting input terminal 302 of the third amplifier 300 while the reference potential V_{ref} is provided to the non-inverting input terminal 304 of the third amplifier 300. The output of the third amplifier 300 is connected to the second terminals 222, 232 of the first amplifier 220 and the second amplifier 230 via a resistance R₃. The second input terminal 222, of the first amplifier 220 is also connected to the third supply 214 via a resistance R₄. The second input terminal 232 of the second amplifier 230 is grounded via a resistance R₄. Thus, as set out in the specification the drain source current I_{DS} can be calculated with:

$${I}_{CS} = {I}_{out , 1} - {I}_{out , 2} = \frac{{I}_{DS}}{N} \frac{{R}_{3}}{{R}_{3} + {R}_{4}} .$$

Otherwise, the embodiment of FIG. 3 corresponds to the embodiment of FIG. 2.

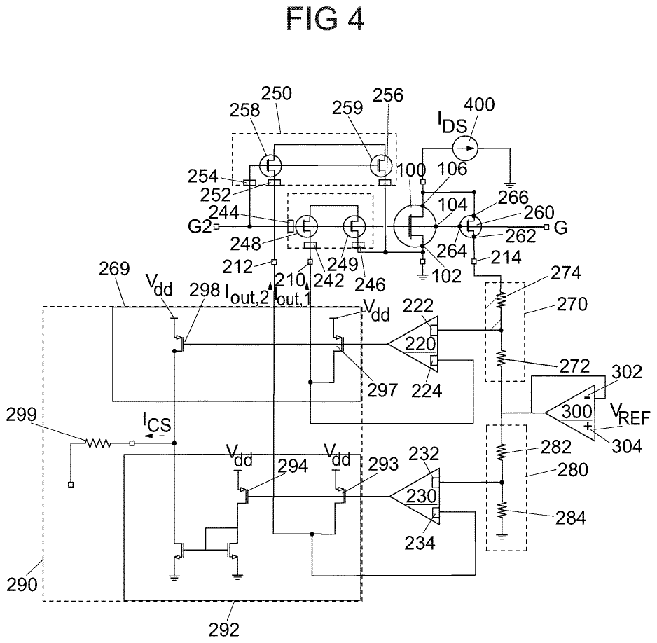

Yet another embodiment of the proposed sensing device with a common reference potential V_{ref} of both voltage adjustment branches 270, 280 is shown in FIG. 4. In contrast to the embodiment shown in FIG. 3 are the gate terminals 104 of the switch transistor 100 and the transistors 248, 249, 258, 259 of the transistor arrangements 240, 250 separated. Accordingly, the gate terminal 104 of the switch transistor 100 is connected to a potential G different to a potential G2 of the gate terminals 244, 254 of the transistor arrangements 240, 250. This ensures that there is no mismatch in a ground source potential between the switch transistor 100 and the transistors 248, 249, 258, 259 of the transistor arrangements 240, 250. Otherwise, the embodiment of FIG. 4 corresponds to the embodiment of FIG. 3.

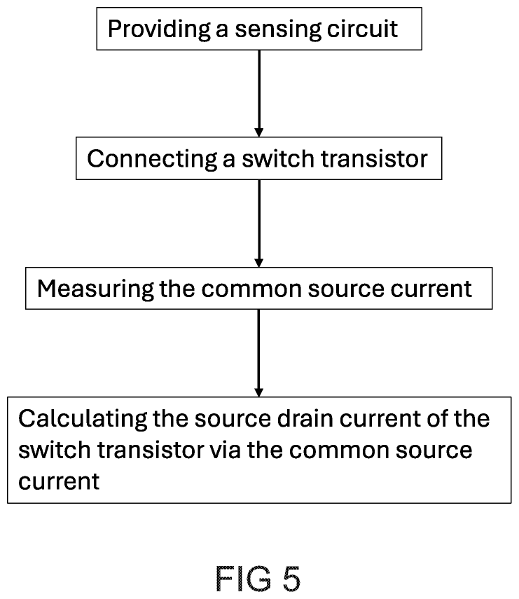

FIG. 5 shows an exemplarily sequence of steps according to the proposed method. The proposed method comprises providing a sensing circuit 200 and connecting it to a switch transistor 100 which means:
providing a first supply 210 connected to a first input terminal 224 of a first operational amplifier 220 and connecting the first supply 210 to a source terminal 102 of the switch transistor 100 via a first transistor arrangement 240;
providing a second supply 212 connected to a first input terminal 234 of a second operational amplifier 230 and connecting the second supply 212 to the source terminal 102 of the switch transistor 100 via a second transistor arrangement 250;
providing a third supply 214 and connecting the third supply 214 to a drain terminal 106 of the switch transistor 100 via a sense transistor 260;
connecting a drain terminal 266 of the sense transistor 260 to a drain terminal 106 of the switch transistor 100 and connecting a gate terminal 264 of the sense transistor 260 to a gate terminal 104 of switch transistor 100;
setting a second terminal 222 of the first amplifier 220 to a first input voltage based on a voltage of the third supply 214 and shifted by an offset; and
setting a second terminal 232 of the second amplifier 230 to the offset.

Subsequently, the common source current I_{CS} of both the first and second amplifier 220, 230 of the sensing circuit 200 is measured for which the output currents I_{out,1}, I_{out,2} of the first amplifier 220 and the second amplifier 230 are superposed. Finally, the source drain current I_{DS} through the switch 100 is calculated based on the superposed output currents and a resistance multiplicity of the transistor arrangements 240, 250 with respect to a resistance of the switch transistor 100. The calculation can be performed with the equations for the source drain current I_{DS} given above.

The proposed solution is not limited to the embodiments discussed in detail here. Rather, the proposed solution comprises any combination of features of the embodiments discussed, insofar as these can be combined in a manner that is feasible for the person skilled in the art.

### REFERENCE NUMERALS

100 switch transistor
102 source terminal
104 gate terminal
106 drain terminal
I_{DS} source drain current
200 sensing circuit
210, 212, 214 supply
220, 230 operational amplifier
Iₒᵤₜ₁, Iₒᵤₜ₂ output current
222, 224, 232, 234 input terminal
240, 250 transistor arrangement
242, 252 source terminal
244, 245, 254 gate terminal
246, 256 drain terminal
248, 249, 258, 259 transistor
G, G2 ground potential
260 sense transistor
262 source terminal
264 gate terminal
266 drain terminal
270, 280 voltage adjustment branch
V_{off} voltage offset
V_{ref} reference voltage
272, 274, 282, 284 resistor
290 output branch
I_{CS} superposed output current
292, 296 current mirror
293,297 input transistor
294, 298 output transistor
V_{dd} potential
299 sense resistor
300 operational amplifier
302, 304 input terminal
400 power device

1. A sensing circuit for sensing a source-drain current through a switch transistor, the sensing circuit comprising:
a first supply connected to a first input terminal of a first operational amplifier and configured to be connected to a source terminal of the switch transistor via a first transistor circuit;
a second supply connected to a first input terminal of a second operational amplifier and configured to be connected to the source terminal of the switch transistor via a second transistor circuit;
a third supply configured to be connected to a drain terminal of the switch transistor via a sense transistor, whereby a gate of the sense transistor is configured to be connected to a gate terminal of the switch transistor;
a first voltage adjustment branch setting a second terminal of the first amplifier to a first Input voltage based on a voltage of the third supply and shifted by an offset;
a second voltage adjustment branch setting a second terminal of the second amplifier to the offset; and
an output branch for superposing output currents of the first amplifier and the second amplifier and measuring the superposed output current.

2. The sensing circuit according to claim 1, wherein the first voltage adjustment branch is configured to provide a first Input voltage which is a voltage (V₃) of the third supply scaled by a factor and shifted by the offset.

3. The sensing circuit according to claim 1, wherein the first voltage adjustment branch comprises a voltage divider for scaling the voltage (V₃) of the third supply.

4. The sensing circuit according to claim 1, wherein the first voltage adjustment branch and the second voltage adjustment branch are configured to reduce voltages on each terminal of both amplifiers to a maximum of 3.3 V.

5. The sensing circuit according to claim 1, wherein the second terminals of both amplifiers are connected to a circuit node with a common reference potential.

6. The sensing circuit according to claim 5, wherein the circuit node is connected to an output of a third operational amplifier providing the reference potential.

7. The sensing circuit according to claim 1, wherein gate terminals of the first transistor circuit and the second transistor circuit are connected to a further circuit node to be set to a common potential.

8. The sensing circuit according to claim 1, wherein the gate terminals of the switch transistor, the first transistor circuit, the second transistor circuit and the sense transistor are connected to a further circuit node to be set to a common potential.

9. The sensing circuit according to claim 1, wherein the first transistor circuit and the second transistor circuit each comprise two transistors.

10. The sensing circuit according to claim 9, wherein the transistors of the first transistor circuit and the second transistor circuit are connected in series.

11. The sensing circuit according to claim 10, wherein the first transistor circuit and the second transistor circuit are identical in construction.

12. The sensing circuit according to claim 1, wherein the output branch comprises at least two current mirrors for superposing the output of the two operational amplifiers.

13. The sensing circuit according to claim 12, wherein each current mirror comprises an input transistor and an output transistor.

14. A sensing device for sensing a current trough a power device with a sensing circuit according to claim 1 and a switch transistor, the switch transistor comprises a source terminal connected to the transistor circuits, a gate terminal connected to the gate terminal of the sense transistor and configured to be connected to the power device.

15. A method for sensing a source-drain current through a switch transistor, comprising:
providing a first supply connected to a first input terminal of a first operational amplifier and connecting the first supply to a source terminal of the switch transistor via a first transistor circuit;
providing a second supply connected to a first input terminal of a second operational amplifier and connecting the second supply the source terminal of the switch transistor via a second transistor circuit;
providing a third supply and connecting the third supply to a drain terminal of the switch transistor via a sense transistor;
providing a connection a gate terminal of the sense transistor with a gate terminal of switch transistor;
setting a second terminal of the first amplifier to a first input voltage based on a voltage of the third supply and shifted by an offset;
setting a second terminal of the second amplifier to the offset;
superposing the output current of the first amplifier and the second amplifier; and
calculating the source-drain current through the switch based on the superposed output current and a resistance multiplicity of the transistor circuits with respect to a resistance of the switch transistor.

16. A sensing circuit comprising:
a first voltage adjustment circuit operative to set a terminal of a first amplifier to a first input voltage based on a received voltage, the received voltage being shifted by an offset value, the first amplifier outputting a first output current;
a second voltage adjustment circuit operative to set a terminal of a second amplifier to the offset value, the second amplifier outputting a second output current; and
an output circuit operative to: i) superimpose the first output current and the second output current to produce a superimposed output current, and ii) measure the superposed output current.
